(19) United States
(12) Patent Application Publication
(10) Pub. No.: US 2024/0322035 A1
(43) Pub. Date: Sep. 26, 2024

(54) SEMICONDUCTOR DEVICE

(71) Applicant: ROHM CO., LTD., Kyoto-shi (JP)

(72) Inventor: Shimpei OHNISHI, Kyoto-shi (JP)

(73) Assignee: ROHM CO., LTD., Kyoto-shi (JP)

(21) Appl. No.: 18/610,288

(22) Filed: Mar. 20, 2024

(30) Foreign Application Priority Data
Mar. 24, 2023 (JP) 2023-048480

(51) Int. Cl. H01L 29/78; H01L 29/06; H01L 29/40; H01L 29/423; H01L 29/66

(52) U.S. Cl. CPC H01L 29/7813; H01L 29/0607; H01L 29/407; H01L 29/4236; H01L 29/66734

(57) ABSTRACT

The present disclosure provides a semiconductor device. The semiconductor device includes: a vertical transistor; and a semiconductor layer, forming a portion of the vertical transistor. The semiconductor layer includes: a first doped layer; a second doped layer, formed on the first doped layer; and a third doped layer, formed on the second doped layer. An impurity concentration of a first conductivity type of the first doped layer is greater than an impurity concentration of the first conductivity type of the third doped layer, and an impurity concentration of the first conductivity type of the second doped layer is less than the impurity concentration of the first conductivity type of the third doped layer.

### CROSS-REFERENCE TO RELATED APPLICATION

This application is based upon and claims the benefit of priority from Japanese patent application no. 2023-048480, filed on Mar. 24, 2023, the entire contents of which are incorporated herein by reference.

### TECHNICAL FIELD

The present disclosure relates to a semiconductor device.

### BACKGROUND

Trench metal-oxide semiconductor field-effect transistors (MOSFETs) are extensively applied in practice in the recent years. In a trench MOSFET, a gate electrode is arranged in a trench in which a semiconductor layer is formed. Patent publication 1 discloses such trench MOSFET.

### PRIOR ART DOCUMENT

### Patent Publication

[Patent document 1] Japan Patent Publication No. 2018-129378

### BRIEF DESCRIPTION OF THE DRAWINGS

FIG. 1 is a brief plan view of an exemplary semiconductor device according to an embodiment.

FIG. 2 is a brief enlarged diagram of a region surrounded by the line F2 in FIG. 2.

FIG. 3 is a brief cross-sectional diagram of a semiconductor device along the line F3-F3 in FIG. 2.

FIG. 4 is brief cross-sectional diagram of an exemplary manufacturing step for a semiconductor device.

FIG. 5 is a brief cross-sectional diagram of a manufacturing step following the step shown in FIG. 4.

FIG. 6 is a brief cross-sectional diagram of a manufacturing step following the step shown in FIG. 5.

FIG. 7 is a brief cross-sectional diagram of a manufacturing step following the step shown in FIG. 6.

FIG. 8 is a brief cross-sectional diagram of a manufacturing step following the step shown in FIG. 7.

FIG. 9 is a brief cross-sectional diagram of a manufacturing step following the step shown in FIG. 8.

FIG. 10 is a brief cross-sectional diagram of a manufacturing step following the step shown in FIG. 9.

FIG. 11 is a brief cross-sectional diagram of a manufacturing step following the step shown in FIG. 10.

FIG. 12 is a brief cross-sectional diagram of a manufacturing step following the step shown in FIG. 11.

FIG. 13 is a brief cross-sectional diagram of a manufacturing step following the step shown in FIG. 12.

FIG. 14(a) to FIG. 14(c) are respectively schematic diagrams of semiconductor layers in semiconductor devices of experiment examples 1 to 3.

FIG. 15 is a table of allowable avalanche currents of the semiconductor devices of experiment examples 1 to 3.

FIG. 16 is a table of on resistances of the semiconductor devices of experiment examples 1 to 3.

### DETAILED DESCRIPTION OF THE EMBODIMENTS

Details of several embodiments of a semiconductor device of the present disclosure are given with the accompanying drawings below. To keep the description clear and simple, the constituting elements shown in the accompanying drawings are not necessarily drawn to fixed downscaled ratios. Moreover, to keep the drawings simple and clear, section lines are sometimes omitted from the cross-sectional diagrams. It should be noted that the accompanying drawings are for illustrating the embodiments of the present disclosure, and are not to be construed as limitations to the present disclosure.

The detailed description below includes a device, a system and a method of the exemplary embodiments of the present disclosure. The detailed description is intended for illustration purposes and is not to be construed as limitations to the embodiments of the present disclosure or applications or uses of these embodiments.

### [Planar Layout of Semiconductor Device)

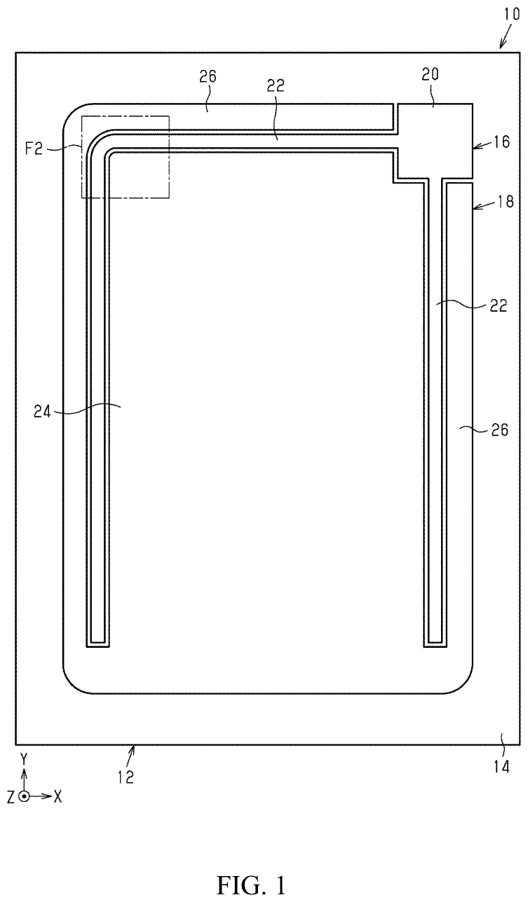

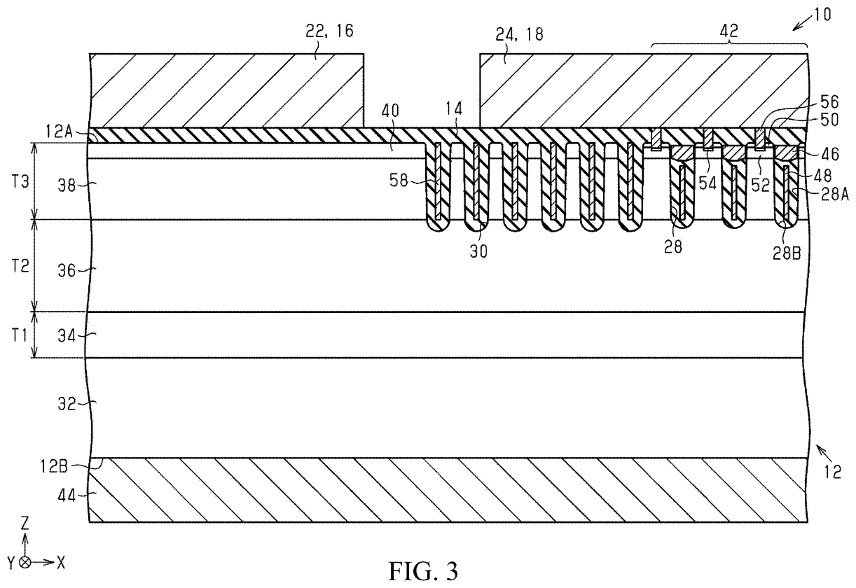

FIG. 1 shows a brief plan view of an exemplary semiconductor device 10 according to an embodiment. The semiconductor device 10 can be formed as a semiconductor chip having a vertical transistor 42 (to be described with reference to FIG. 3 below). The semiconductor device 10 includes a semiconductor layer 12. The semiconductor layer 12 can be formed of silicon (Si). The Z-axis direction of X, Y and Z axes perpendicular to one another is a direction substantially perpendicular to a first surface 12A of the semiconductor layer 12. Moreover, unless otherwise specified, the term “plan view” used in the present detailed description refers to observing the semiconductor device 10 from the Z-axis direction.

The semiconductor device 10 can further include an insulating layer 14 formed on the semiconductor layer 12. The insulating layer 14 is formed of at least one of silicon oxide (SiO₂) and silicon nitride (SiN).

The semiconductor device 10 can further include a gate wiring 16 formed on the insulating layer 14, and a source wiring 18 formed on the insulating layer 14 and separated from the gate wiring 16. The gate wiring 16 and the source wiring 18 can be made formed of at least one of titanium (Ti), nickel (Ni), gold (Au), silver (Ag), copper (Cu), aluminum (Al), Cu alloy and Al alloy.

The gate wiring 16 can include a gate pad 20, and one or more gate extension portions 22. The gate pad 20 is electrically coupled to the one or more gate extension portions 22. The gate pad 20 and the one or more gate extension portions 22 can be formed as an integral. In the example in FIG. 1, the gate pad 20 is disposed on a corner of the semiconductor layer 12 in the plan view, and is connected to two gate extension portions 22. One between the two gate extension portions 22 extends from the gate pad 20 in the Y direction. The other between the two gate extension portions 22 is formed to have an L shape in the plan view. In a layout example, the layout of the gate wiring 16 including the gate pad 20 and the gate extension(s) 22 can be appropriately determined according to characteristics needed by the semiconductor device 10.

The source wiring 18 can include an inner section 24 at least partially surrounded by the gate wiring 16, and a peripheral section 26 (also referred to as a source finger) at least surrounding the gate wiring 16. The inner section 24 and the peripheral section 26 are electrically coupled to each other.

### [Configuration of Gate Trench]

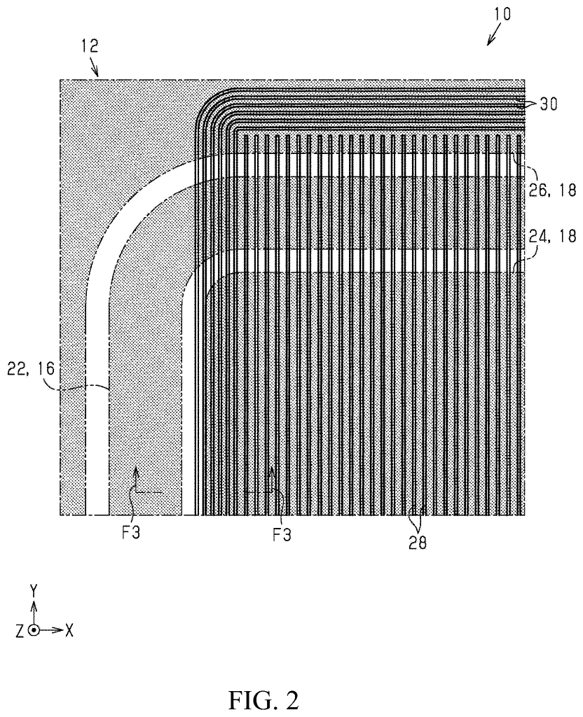

FIG. 2 shows a brief enlarged diagram of a region surrounded by the line F2 in FIG. 1. For better illustration, the insulating layer 14 (and any constituting element possibly formed in the insulating layer 14) is omitted from FIG. 2, and the gate wiring 16 and the source wiring 18 are represented by double-dot dashed lines.

The semiconductor device 10 can further include one or more gate trenches 28 formed in the semiconductor layer 12. In the example in FIG. 2, the semiconductor device 12 includes a plurality of gate trenches 28 disposed in strip shapes in the plan view. The plurality of gate trenches 28 extend in the Y-axis direction, and are arranged in the X-axis direction. The plurality of gate trenches 28 can also be arranged at fixed intervals from one another. Moreover, the semiconductor device 10 can further include a plurality of other gate trenches (omitted from the drawing) extending in the X-axis direction and arranged in the Y-axis direction.

The gate trenches 28 can be disposed to at least partially overlap the gate wiring 16 and the source wiring 18 in the plan view. In the example in FIG. 2, the gate trenches 28 can extend to overlap the gate extension portions 22 and the inner section 24 of the source wiring 18 in the plan view. Moreover, one end of the gate trench 28 overlaps the peripheral section 26 of the source wiring 18.

The semiconductor device 10 can further include one or more peripheral trenches 30 formed in the semiconductor layer 12. The one or more (6 in the example in FIG. 2) peripheral trenches 30 can be formed to have a loop shape to surround the one or more gate trenches 28 in the plan view. In the example in FIG. 2, the peripheral trenches 30 are formed to have a loop shape (FIG. 2 depicts rounded corner portions and peripherals of the peripheral trenches 30) in the plan view.

### [Cross-Section Structure of Semiconductor Device)

FIG. 3 shows a brief cross-sectional diagram of the semiconductor device 10 along the line F3-F3 in FIG. 2. As shown in FIG. 3, the semiconductor layer 12 has a first surface 12A and a second surface 12B on a side opposite to the first surface 12A. The insulating layer 14 is formed on the first surface 12A of the semiconductor layer 12.

The semiconductor layer 12 can include a semiconductor substrate 32. The semiconductor substrate 32 can include the second surface 12B of the semiconductor layer 12. The semiconductor substrate 32 can be an n-type Si substrate. In one example, a thickness of the semiconductor substrate 32 can be, for example, between about 10 μm and about 450 μm. Moreover, an n-type impurity concentration of the semiconductor substrate 32 can be between about 1×10¹⁸ cm⁻³ and 1×10²¹ cm⁻³. In addition, in the present detailed description, the n type is also referred to as a first conductivity type and the p type is also referred to as a second conductivity type. The n-type impurity can be, for example, phosphorous (P) and arsenic (As). Moreover, the p-type impurity can be, for example, boron (B) and aluminum (Al). A resistivity of the semiconductor substrate 32 can be between about 0.5 mΩ·cm and about 5 mΩ·cm.

The semiconductor layer 12 includes a first doped layer 34, a second doped layer 36 formed on the first doped layer 34, and a third doped layer 38 formed on the second doped layer 36. The first doped layer 34 can be formed on the semiconductor substrate 32. Moreover, the third doped layer 38 can include the first surface 12A of the semiconductor layer 12. That is to say, the insulating layer 14 can be formed on the third doped layer 38.

The first doped layer 34, the second doped layer 36 and the third doped layer 38 can be formed of Si. Moreover, the first doped layer 34, the second doped layer 36 and the third doped layer 38 can be Si epitaxial layers.

The first doped layer 34, the second doped layer 36 and the third doped layer 38 can be doped with n-type impurities. An n-type impurity concentration of the first doped layer 34 is greater than an n-type impurity concentration of the third doped layer 38. Moreover, an n-type impurity concentration of the second doped layer 36 is less than the n-type impurity concentration of the third doped layer 38. In one example, the n-type impurity concentration of the first doped layer 34 can be between about 1×10¹⁶ cm⁻³ and 1×10¹⁹ cm⁻³, the n-type impurity concentration of the second doped layer 36 can be between about 1×10¹³ cm⁻³ and 1×10¹⁶ cm⁻³, and the n-type impurity concentration of the third doped layer 38 can be between about 2×10¹⁵ cm⁻³ and 1×10¹⁸ cm⁻³.

A resistivity of the first doped layer 34 is less than a resistivity of the third doped layer 38. Moreover, a resistivity of the second doped layer 36 is greater than the resistivity of the third doped layer 38. In one example, the resistivity of the first doped layer 34 can be between about 0.01 Ω·cm and about 0.5 Ω·cm, the resistivity of the second doped layer 36 can be between about 0.1 Ω·cm and about 10 Ω·cm, and the resistivity of the third doped layer 38 can be between about 0.05 Ω·cm and about 1 Ω·cm.

The impurity concentration and resistivity distribution in the semiconductor layer 12 can be measured by, for example, spreading resistance analysis and secondary ion mass spectrometry (SIMS).

In addition, the impurity concentration can also be an average value, a maximum value or a minimum value of the impurity concentration of each of the layers, or can be a value of the impurity concentration at a middle position of each of the layers in the thickness direction. Similarly, the resistivity can be an average value, a maximum value or a minimum value of the resistivity of each of the layers, or can be a value of the resistivity at a middle position of each of the layers in the thickness direction.

The first doped layer 34 can be thinner than the third doped layer 38. Moreover, the second doped layer 36 can be thicker than the third doped layer 38. That is to say, a relationship of a thickness T1 of the first doped layer 34, a thickness T2 of the second doped layer 36 and a thickness T3 of the third doped layer 38 can be represented as T2>T3>T1. In addition, the thickness T1 of the first doped layer 34, the thickness T2 of the second doped layer 36 and the thickness T3 of the third doped layer 38 are equivalent to sizes of the first doped layer 34, the second doped layer 36 and the third doped layer 38 in the Z-axis direction. In one example, the thickness T1 of the first doped layer 34 can be between about 0.5 μm and about 10 μm, the thickness T2 of the second doped layer 36 can be between about 1 μm and about 30 μm, and the thickness T3 of the third doped layer 38 can be between about 1 μm and about 15 μm.

In addition, the first doped layer 34, the second doped layer 36 and/or the third doped layer 38 can be formed to have various ion implantation regions. For example, the third doped layer 38 can be formed to have a p-type ion implantation region 40. As shown in FIG. 3, the ion implantation region 40 can be formed in a surface layer portion of the third doped layer 38. In one example, a p-type impurity concentration of the ion implantation region 40 can be between about 1×10¹⁵ cm⁻³ and about 1×10¹⁸ cm⁻³. It should be noted that the thickness T3 of the third doped layer 38 includes a thickness of the ion implantation region 40.

The semiconductor device 10 includes a vertical transistor 42. In this embodiment, the vertical transistor 42 can be a trench MOSFET. The semiconductor device 12 forms a portion of the vertical transistor 42. The vertical transistor 42 can be formed in a region where the gate trench 28 is disposed. The semiconductor device 10 can further include a drain electrode 44 formed on the second surface 12B of the semiconductor layer 12. The drain electrode 44 can be formed of at least one of titanium (Ti), nickel (Ni), gold (Au), silver (Ag), copper (Cu), aluminum (Al), Cu alloy and Al alloy. The vertical transistor 42 is configured to be able to control the flow of electrons in a vertical direction (the Z-axis direction) between the source wiring 18 and the drain electrode 44 via a channel formed in the semiconductor layer 12. When the vertical transistor 42 is turned on, an electric current can flow through the first doped layer 34, the second doped layer 36 and the third doped layer 38.

The gate trench 28 has an opening on the first surface 12A of the semiconductor layer 12, and has a depth in the Z-axis direction. More specifically, the gate trench 28 can pass through the third doped layer 38 and reach the second doped layer 36. In one example, the gate trench 28 can have a depth of between about 2 μm and about 10 μm. Preferably, the gate trench 28 can have a depth greater than the thickness T3 of the third doped layer 38.

A sidewall 28A of the gate trench 28 can extend in the Z-axis direction, or can be inclined with respect to the Z-axis direction. For example, the sidewall 28A can be inclined with respect to the Z-axis direction to have a width (a size in the X-axis direction in the example in the drawing) of the gate trench 28 decrease toward a bottom wall 28B of the gate trench 28. The gate trench 28 can have at least a portion formed on the bottom wall 28B of the second doped layer 36. The bottom wall 28B of the gate trench 28 is not necessarily flat, but can be, for example, partially or entirely curved.

The semiconductor device 10 can further include a gate electrode 46 disposed in the gate trench 28. The gate electrode 46 can be buried in the gate trench 28 across from the insulating layer 14. The gate electrode 46 can be electrically coupled to the gate wiring 16. The gate electrode 46 can be connected to the gate wiring 16 via one or more contact plugs (omitted from the drawing), wherein the one or more contact plugs are disposed in an intersecting region of the gate trench 28 and the gate wiring 16 (the gate extension portions 22) in the plan view. Accordingly, a gate voltage can be applied to the gate electrode 46.

The semiconductor device 10 can further include a field electrode 48 disposed in the gate trench 28. The field electrode 48 can be buried in the gate trench 28 across from the insulating layer 14. The field electrode 48 can be disposed between the gate electrode 46 and the bottom wall 28B of the gate trench 28. The gate electrode 46 and the field electrode 48 are separated by the insulating layer 14. As shown in FIG. 3, the field electrode 48 can have a size smaller than that of the gate electrode 46 in the X-axis direction. Accordingly, the insulating layer 14 between the field electrode 48 and the sidewall 28A can have a larger thickness. The field electrode 48 can be electrically coupled to the source wiring 18. The field electrode 48 can be connected to the source wiring 18 via one or more contact plugs (omitted from the drawing), wherein the one or more contact plugs are disposed in an intersecting region (referring to FIG. 2) of the gate trench 28 and the source wiring 18 (the inner section 24 and/or the peripheral section 26) in the plan view. Accordingly, a source voltage (or a reference voltage) can be applied to the field electrode 48.

The gate electrode 46 and the field electrode 48 can be formed of conductive polysilicon. In another example, the gate electrode 46 and/or the field electrode 48 can also be formed of any other metal material as desired.

An n-type source region 50 can be formed on a surface layer portion of the ion implantation region 40 adjacent to the gate trench 28. Moreover, a portion other than the source region 50 in the ion implantation region 40 adjacent to the gate trench 28 is equivalent to a body region 52 of the vertical transistor 42. In one example, an n-type impurity concentration of the source region 50 can be between about 1×10¹⁹ cm⁻³ and 1×10²¹ cm⁻³. It should be noted that the thickness T3 of the third doped layer 38 includes a thickness of the source region 50.

As such, the p-type body region 52 and the n-type source region 50 of the vertical transistor 42 can be formed in the third doped layer 38. By applying a specified gate voltage to the gate electrode 46, a channel can be formed in a portion of the body region 52 close to the gate electrode 46. Moreover, a portion other than the ion implantation region 40 in the third doped layer 38, the second doped layer 36 and the first doped layer 34 can be equivalent to a drift region of the vertical transistor 42. The semiconductor substrate 32 can be equivalent to a drain region of the vertical transistor 42.

Further, a contact region 54 can be formed in the ion implantation region 40 adjacent to the gate trench 28. The contact region 54 can include a p-type region including p-type impurities. A p-type impurity concentration of the contact region 54 is greater than that of the body region 52 (the ion implantation region 40), and can be between about 1×10¹⁹ cm⁻³ and about 1×10²¹ cm⁻³ in one example.

The semiconductor device 10 can further include a source contact plug 56 connected to the source wiring 18. The source wiring plug 56 extends to pass through the insulating layer 14 and the source region 50 and be in contact with the contact region 54. The contact region 54 is electrically coupled to the source wiring 18 via the source contact plug 56.

The peripheral trench 30 has an opening on the first surface 12A of the semiconductor layer 12, and has a depth in the Z-axis direction. More specifically, the semiconductor trench 30 can pass through the third doped layer 38 and reach the second doped layer 36. In one example, the peripheral trench 30 can be formed to have a same width and a same depth as those of the gate trench 28. In another example, the peripheral trench 30 can also have a different width and/or a different depth from those/that of the gate trench 28. For example, the peripheral trench 30 can have a width and a depth greater than those of the gate trench 28. The peripheral trench 30 can be formed to surround the vertical transistor 42 in the plan view.

The semiconductor device 10 can further include a peripheral electrode 58 disposed in the peripheral trench 30. The peripheral electrode 58 can be buried in the peripheral trench 30 across from the insulating layer 14. The peripheral electrode 58 can be electrically coupled to the source wiring 18. The peripheral electrode 58 can be connected to the source wiring 18 via one or more contact plugs (omitted from the drawing), wherein the one or more contact plugs are disposed in an intersecting region (referring to FIG. 2) of the peripheral trench 30 and the source wiring 18 (the peripheral section 26) in the plan view. Accordingly, a source voltage (or a reference voltage) can be applied to the peripheral electrode 58.

When a plurality of peripheral trenches 30 are used as the example in FIG. 3, it is not necessary for each of the plurality of peripheral trenches 30 have the same width and the same depth. Moreover, the plurality of peripheral trenches 30 can also be arranged at an interval less than an arrangement interval of the gate trench 28.

### [Method for Manufacturing Semiconductor Device]

Next, an example of a method for manufacturing the semiconductor device 10 is described below.

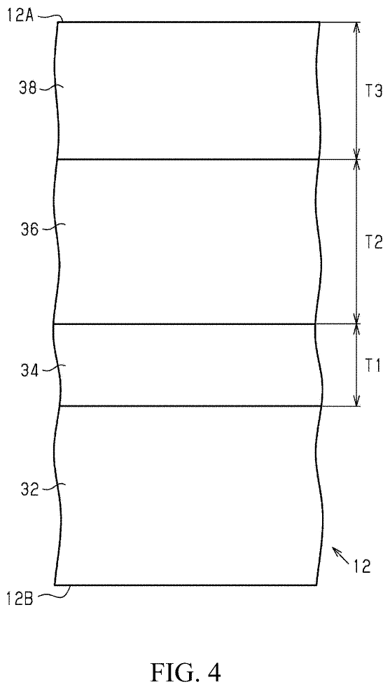

FIG. 4 to FIG. 13 show brief cross-sectional diagrams of exemplary manufacturing steps for the semiconductor device 10. In FIG. 4 to FIG. 13, a cross section of the semiconductor device 10, more particularly a portion forming the vertical transistor 42, is depicted. Moreover, for better understanding, in FIG. 4 to FIG. 13, the constituting elements the same as the constituting elements in FIG. 3 are denoted by the same numerals or symbols.

As shown in FIG. 4, the method for manufacturing the semiconductor device 10 includes forming the semiconductor layer 12 having the first surface 12A and the second surface 12B on a side opposite to the first surface 12A. The forming of the semiconductor layer 12 can include forming the first doped layer 34 on the semiconductor substrate 32, forming the second doped layer 36 on the first doped layer 34, and forming the third doped layer 38 on the second doped layer 36. The semiconductor substrate 32 can be a Si substrate including n-type impurities. The first doped layer 34, the second doped layer 36 and the third doped layer 38 can be Si layers epitaxially grown on the semiconductor substrate 32. The first doped layer 34, the second doped layer 36 and the third doped layer 38 can be grown continuously while being doped with n-type impurities. By changing the doping amount of n-type impurities during epitaxial growth, the first doped layer 34, the second doped layer 36 and the third doped layer 38 having different doping concentrations of n-type impurities can be obtained.

An n-type impurity concentration of the first doped layer 34 is greater than an n-type impurity concentration of the third doped layer 38. Moreover, an n-type impurity concentration of the second doped layer 36 is less than the n-type impurity concentration of the third doped layer 38. In one example, the n-type impurity concentration of the first doped layer 34 can be between about 1×10¹⁶ cm⁻³ and 1×10¹⁹ cm⁻³, the n-type impurity concentration of the second doped layer 36 can be between about 1×10¹³ cm⁻³ and 1×10¹⁶ cm⁻³, and the n-type impurity concentration of the third doped layer 38 can be between about 2×10¹⁵ cm⁻³ and 1×10¹⁸ cm⁻³.

A resistivity of the first doped layer 34 is less than a resistivity of the third doped layer 38. Moreover, a resistivity of the second doped layer 36 is greater than the resistivity of the third doped layer 38. In one example, the resistivity of the first doped layer 34 can be between about 0.01 Ω·cm and about 0.5 Ω·cm, the resistivity of the second doped layer 36 can be between about 0.1 Ω·cm and about 10 Ω·cm, and the resistivity of the third doped layer 38 can be between about 0.05 Ω·cm and about 1 Ω·cm.

The first doped layer 34 can be thinner than the third doped layer 38. Moreover, the second doped layer 36 can be thicker than the third doped layer 38. That is to say, a relationship of a thickness T1 of the first doped layer 34, a thickness T2 of the second doped layer 36 and a thickness T3 of the third doped layer 38 can be represented as T2>T3>T1. In one example, the thickness T1 of the first doped layer 34 can be between about 0.5 μm and about 10 μm, the thickness T2 of the second doped layer 36 can be between about 1 μm and about 30 μm, and the thickness T3 of the third doped layer 38 can be between about 1 μm and about 15 μm.

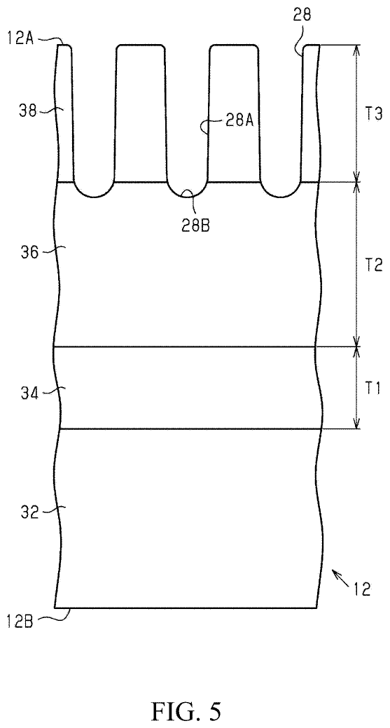

FIG. 5 is a brief cross-sectional diagram of a manufacturing step following the step shown in FIG. 4; as shown in FIG. 5, the method for manufacturing the semiconductor device 10 can further include forming the gate trench 28 in the semiconductor layer 12. More specifically, a mask (not shown) of a predetermined pattern is formed on the first surface 12A of the semiconductor layer 12, and then a portion of the semiconductor layer 12 is selectively removed by etching using the mask.

The gate trench 28 has an opening on the first surface 12A of the semiconductor layer 12, and has a depth in the Z-axis direction. More specifically, the gate trench 28 can pass through the third doped layer 38 and reach the second doped layer 36. In one example, the gate trench 28 can have a depth of between about 2 μm and about 10 μm. Preferably, the gate trench 28 can have a depth greater than the thickness T3 of the third doped layer 38. As a result, a least a portion of the bottom wall 28B of the gate trench 28 is formed in the second doped layer 36. In the example shown in the drawing, the bottom wall 28B of the gate trench 28 is curved, but can also include a flat portion.

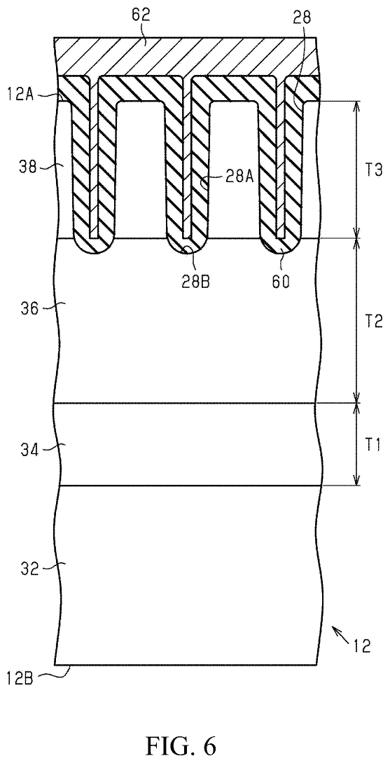

FIG. 6 shows a brief cross-sectional diagram of a manufacturing step following the step shown in FIG. 5. As shown in FIG. 6, the method for manufacturing the semiconductor device 10 can further include forming a first insulating layer 60 on the first surface 12A of the semiconductor layer 12 and the gate trench 28, and forming a first conductive layer 62 on the first insulating layer 60. More specifically, the first insulating layer 60 is formed along the first surface 12A of the semiconductor layer 12, and the sidewall 28A and the bottom wall 28B of the gate trench 28. In one example, the first insulating layer 60 is SiO₂ formed by thermal oxidation. In another example, the first insulation layer 60 can also be formed by chemical vapor deposition (CVD). The first conductor layer 62 can be, for example, conductive polysilicon. The gate trench 28 is buried by the first insulating layer 60 and the first conductor layer 62 formed on the first insulating layer 60.

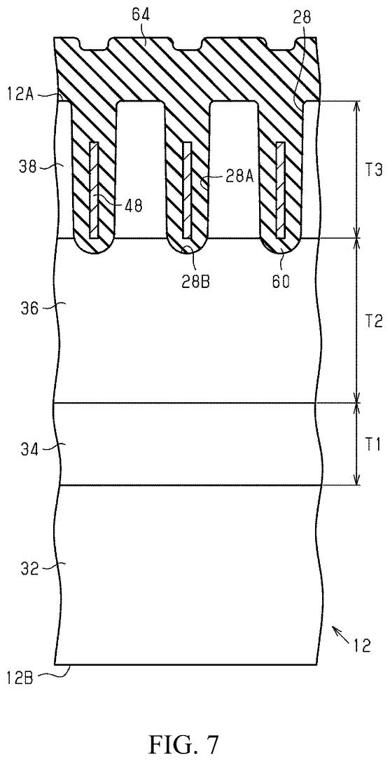

FIG. 7 shows a brief cross-sectional diagram of a manufacturing step following the step shown in FIG. 6. As shown in FIG. 7, the method for manufacturing the semiconductor device 10 can further include forming the field electrode 48. The field electrode 48 is formed by removing a portion of the first conductor layer 62 (referring to FIG. 6) by etching. Then, a second insulating layer 64 covering the field electrode 48 and burying the gate trench 28 is formed. The second insulating layer 54 is similarly formed of SiO₂ as the first insulating layer 60. The second insulating layer 64 can be SiO₂ formed by CVD, or can be SiO₂ formed by thermal oxidation. Moreover, before the second insulating layer 64 is formed, a portion of the first insulating layer 60 (referring to FIG. 6) is removed by etching. In FIG. 7, the second insulating layer 64 and at least a portion of the first insulating layer 60 are integrally shown.

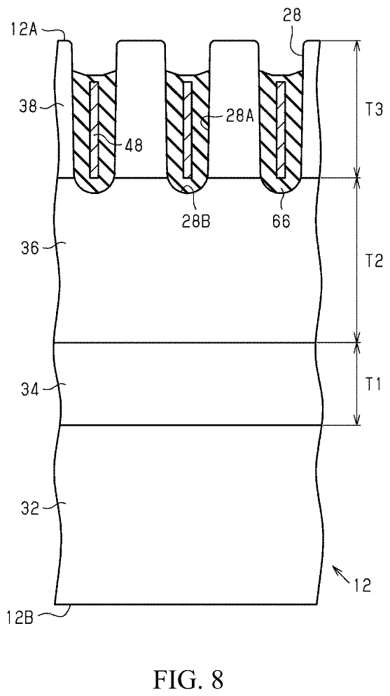

FIG. 8 shows a brief cross-sectional diagram of a manufacturing step following the step shown in FIG. 7. As shown in FIG. 8, the method for manufacturing the semiconductor device 10 can further include partially removing the first insulating layer 60 and the second insulating layer 64 (referring to FIG. 7) to form a lower insulating portion 66. The lower insulating portion 66 is equivalent to a residual portion after etching the first insulating layer 60 and the second insulating layer 64. As a result, the first surface 12A of the semiconductor layer 12 and a portion of the sidewall 28A are exposed.

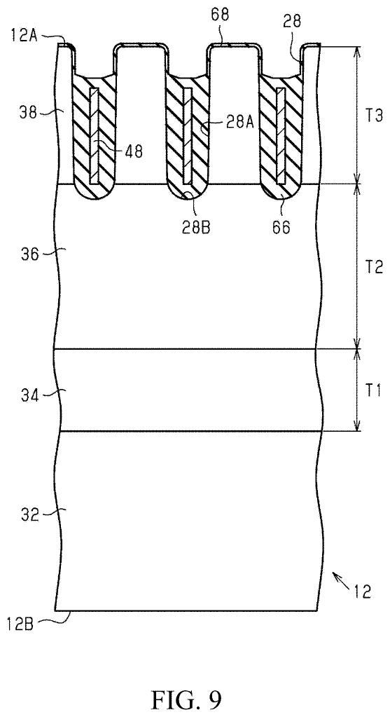

FIG. 9 shows a brief cross-sectional diagram of a manufacturing step following the step shown in FIG. 8. As shown in FIG. 9, the method for manufacturing the semiconductor device 10 can further include forming a third insulating layer 68 on the semiconductor layer 12 and the lower insulating portion 66. The third insulating layer 68 has a smaller thickness, and can cover an upper portion of the sidewall 28A of the gate trench 28. In one example, the third insulating layer 68 is SiO₂ formed by thermal oxidation. In another example, the third insulating layer 68 can also be formed by CVD.

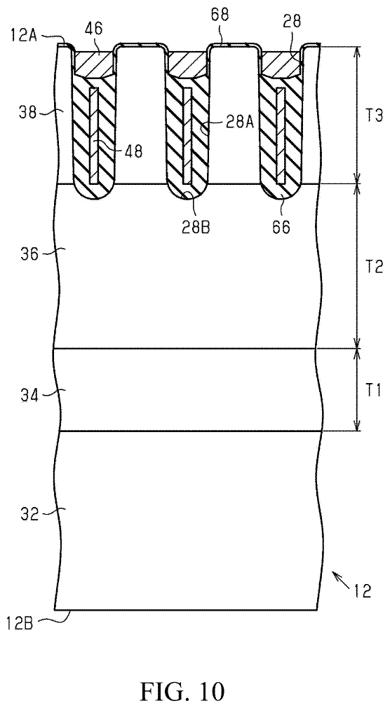

FIG. 10 shows a brief cross-sectional diagram of a manufacturing step following the step shown in FIG. 9. As shown in FIG. 10, the method for manufacturing the semiconductor device 10 can further include forming the gate electrode 46. The gate electrode 46 can be formed by etching a remaining portion after forming a conductor layer (omitted from the drawing) on the third insulating layer 68. The gate electrode 46 can be formed of, for example, conductive polysilicon. As a result, the gate electrode 46 faces the sidewall 28A of the gate trench 28 across from the third insulating layer 68.

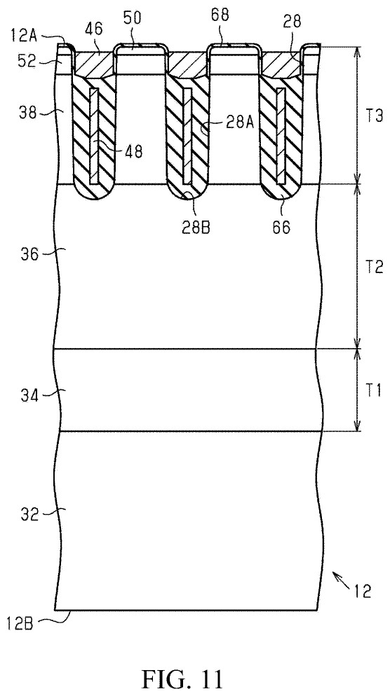

FIG. 11 shows a brief cross-sectional diagram of a manufacturing step following the step shown in FIG. 10. As shown in FIG. 11, the method for manufacturing the semiconductor device 10 can further include forming the source region 50 and the body region 52 in the third doped layer 38. More specifically, after forming the p-type ion implantation region 40 (referring to FIG. 3) in the third doped layer 38, the n-type source region 50 is formed on the surface portion of the ion implantation region 40, accordingly forming the body region 52. The body region 52 is equivalent to a portion other than the source region 50 in the ion implantation region 40.

The body region 52 is formed to face at least a portion of the gate electrode 46 across from the third insulating layer 68. Accordingly, when a gate voltage is applied to the gate electrode 46, a channel can be formed in the body region 52.

The n-type impurity concentration of the source region 50 can be between about 1×10¹⁹ cm⁻³ and 1×10²¹ cm⁻³. Moreover, the p-type impurity concentration of the body region 52 can be between about 1×10¹⁵ cm⁻³ and about 1×10¹⁸ cm⁻³.

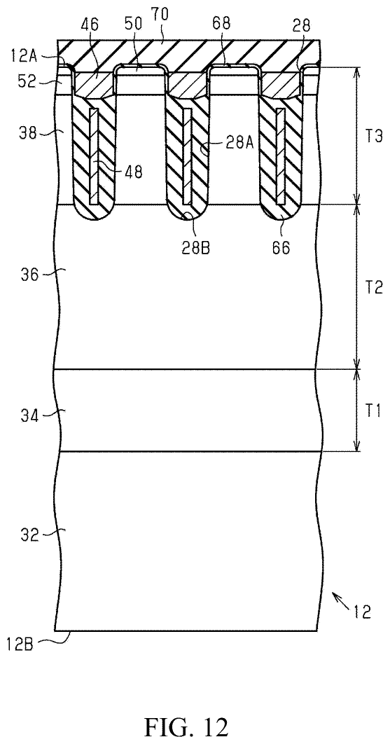

FIG. 12 shows a brief cross-sectional diagram of a manufacturing step following the step shown in FIG. 11. As shown in FIG. 12, the method for manufacturing the semiconductor device 10 can further include forming a fourth insulating layer 70 on the third insulating layer 68 and the gate electrode 46. In one example, the fourth insulating layer 70 can also be formed by CVD. Moreover, the fourth insulating layer 70, the third insulating layer 68 and the lower insulating portion 66 can form the insulating layer 14 in FIG. 3.

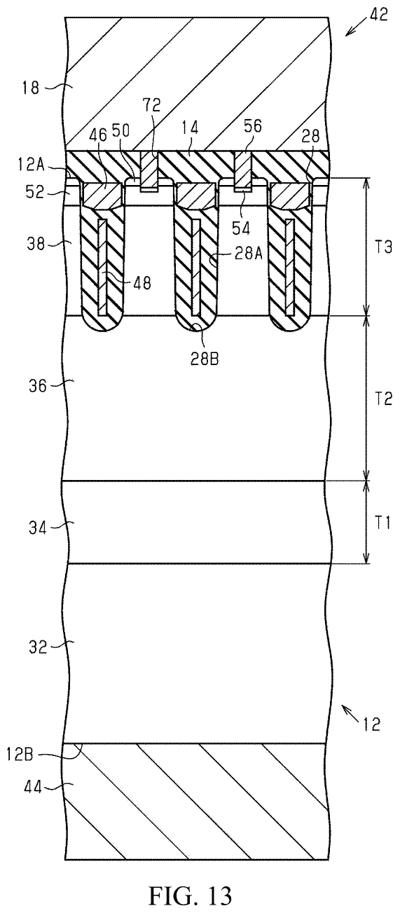

FIG. 13 shows a brief cross-sectional diagram of a manufacturing step following the step shown in FIG. 12. As shown in FIG. 13, the method for manufacturing the semiconductor device 10 can further include forming the contact region 54 and the source contact plug 56, forming the source wiring 18 on the insulating layer 14, and forming the drain electrode 44 on the second surface 12B of the semiconductor layer 12. More specifically, a source contact hole 72 passing through the insulating layer 14 and reaching the semiconductor layer 12 is formed. Then, the contact region 54 is formed by implanting p-type impurities from a bottom of the source contact hole 72. The source contact plug 56 is formed in the source contact hole 72, and then the source wiring 18 is formed on the insulating layer 14. The drain electrode 44 is formed on the second surface 12B of the semiconductor layer 12. The vertical transistor 42 of the semiconductor device 10 is formed by the steps above.

### [Effects of Semiconductor Device]

Effects of the semiconductor device 10 according to this embodiment are described below. The semiconductor device 10 includes a vertical transistor 42, and a semiconductor layer 12 forming a portion of the vertical transistor 42. The semiconductor layer 12 includes a first doped layer 34, a second doped layer 36 formed on the first doped layer 34, and a third doped layer 38 formed on the second doped layer 36. An n-type impurity concentration of the first doped layer 34 is greater than an n-type impurity concentration of the third doped layer 38, and an n-type impurity concentration of the second doped layer 36 is less than the n-type impurity concentration of the third doped layer 38.

Since the semiconductor layer 12 includes the first doped layer 34 having a greater n-type impurity concentration (a smaller resistivity), the thickness of the semiconductor layer 12 can be increased, and an increase in the on resistance can be suppressed. Moreover, the avalanche allowance of the semiconductor device 10 can be further increased as the thickness of the semiconductor layer 12 increases. Thus, the semiconductor device 10 according to this embodiment is able to suppress an increase in the on resistance and increase the avalanche allowance.

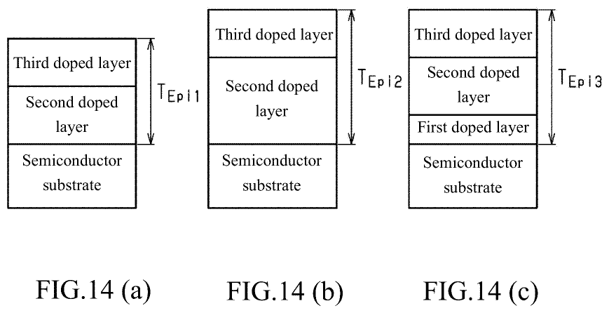

Referring to FIG. 14 to FIG. 16, how the semiconductor device 10 of this embodiment increases the avalanche allowance and suppresses an increase in the on resistance are described in detail below.

FIG. 14(a) to FIG. 14(c) respectively show schematic diagrams of semiconductor layers in semiconductor devices of experiment examples 1 to 3. The semiconductor devices of experimental example 1 and experiment example 2 shown in FIG. 14(a) and FIG. 14(b) differ from the semiconductor device 10 of this embodiment substantially in that, a semiconductor layer does not include a first doped layer. That is to say, in each of experiment example 1 and experiment example 2, the semiconductor layer includes a semiconductor substrate, a second doped layer formed on the semiconductor substrate, and a third doped layer formed on the second doped layer. On the other hand, experiment example 3 shown in FIG. 14(c) corresponds to the semiconductor device 10 of this embodiment. That is to say, in experiment example 3, the semiconductor layer includes a semiconductor substrate, a first doped layer formed on the semiconductor substrate, a second doped layer formed on the first doped layer, and a third doped layer formed on the second doped layer. The relationship of n-type impurity concentrations of the first doped layer, the second doped layer and the third doped layer in each of experiment examples 1 to 3 is the same as that of this embodiment. That is to say, the n-type impurity concentration of the first doped layer is greater than the n-type impurity concentration of the third doped layer, and the n-type impurity concentration of the second doped layer is less than the n-type impurity concentration of the third doped layer. Thus, a resistivity of the first doped layer is less than a resistivity of the third doped layer, and a resistivity of the second doped layer is greater than the resistivity of the third doped layer.

A thickness of the second doped layer of experiment example 1 is equal to a thickness of the second doped layer of experiment example 3, and a thickness of the third doped layer of experiment example 1 is equal to a thickness of the third doped layer of experiment example 3. Thus, a total thickness T_{Epi1} (a total thickness of the second doped layer and the third doped layer) of doped layers formed on the semiconductor substrate of experiment example 1 is less than a total thickness T_{Epi3} (a total thickness of the first doped layer, the second doped layer and the third doped layer) of doped layers formed on the semiconductor substrate of experiment example 3.

The second doped layer of experiment example 2 has a thickness greater than those of the second doped layers of experiment example 1 and experiment example 3. More specifically, the thickness of the second doped layer of experiment example 2 is equal to a total thickness of the first doped layer and the second doped layer of experiment example 3. Accordingly, a total thickness T_{Epi2} (a total thickness of the second doped layer and the third doped layer) of doped layers formed on the semiconductor substrate of experiment example 2 is equal to the total thickness T_{Epi3} (the total thickness of the first doped layer, the second doped layer and the third doped layer) of doped layers formed on the semiconductor substrate of experiment example 3.

Except for the aspect of the semiconductor layer, the semiconductor devices of experiment example 1, experiment example 2 and experiment example 3 are substantially the same.

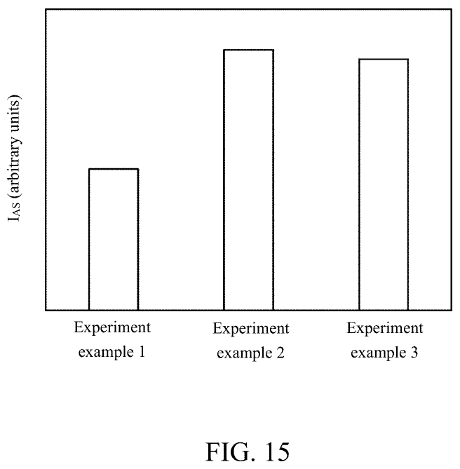

FIG. 15 shows a table of allowable avalanche currents of the semiconductor devices of experiment examples 1 to 3. The allowable avalanche current is a maximum value of an avalanche current that is allowed when an avalanche breakdown is generated in a semiconductor device. In the table in FIG. 15, the vertical axis denoted as I_{AS} represents an allowable avalanche current of a semiconductor device.

As shown in FIG. 15, the allowable avalanche current of experiment example 1 is less than the allowable avalanche currents of experiment examples 2 and 3 by 40% or more. On the other hand, the allowable avalanche current of experiment example 2 is substantially equal to the allowable avalanche current of experiment example 3 (with a difference within 5%).

This means that the allowable avalanche current of a semiconductor device is determined by a total thickness of doped layers on a semiconductor substrate. The total thickness T_{Epi1} of the doped layers of experiment example 1 is less than the total thicknesses T_{Epi2} and T_{Epi3} of the doped layers of experiment examples 2 and 3, and the total thickness T_{Epi2} of the doped layers of experiment example 2 is equal to the total thickness T_{Epi3} of the doped layers of experiment example 3.

Thus, by increasing the total thickness of doped layers formed on a semiconductor substrate, the allowable avalanche current of a semiconductor device can be increased.

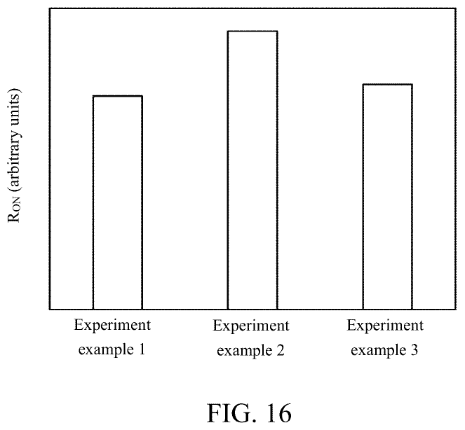

On the other hand, FIG. 16 shows a table of on resistances of the semiconductor devices of experiment examples 1 to 3. In the table in FIG. 16, the vertical axis denoted as RON represents an on resistance of a semiconductor device.

As shown in FIG. 16, the on resistance of experiment example 2 is greater than the on resistance of experiment example 1. The reason for the above is that, the total thickness T_{Epi2} of the doped layers of experiment example 2 is greater than the total thickness T_{Epi1} of the doped layers of experiment example 1. More specifically, since the thickness of the second doped layer of experiment example 2 is greater than the thickness of the second doped layer of experiment example 1, the on resistance of experiment example 2 is greater than the on resistance of experiment example 1.

On the other hand, the total thickness T_{Epi3} of the doped layers of experiment example 3 is equal to the total thickness T_{Epi2} of the doped layers of experiment example 2, but the on resistance of experiment example 3 is less than the on resistance of experiment example 2. The reason for the above is that, the semiconductor layer of experiment example 3 includes the first doped layer having a smaller resistivity. Since the semiconductor layer includes the first doped layer, the thickness of the second doped layer having a larger resistivity can be reduced in experiment example 3.

As such, even if the total thickness T_{Epi3} of the doped layers of experiment example 3 is equal to the total thickness T_{Epi2} of the doped layers of experiment example 2, unlike the on resistance of experiment example 2, the on resistance of experiment example 3 is not increased with respect to the on resistance of experiment example 1. Moreover, because the total thickness T_{Epi3} of the doped layers of experiment example 3 is greater than the total thickness T_{Epi1} of the doped layers of experiment example 1, the allowable avalanche current of the semiconductor device of experiment example 3 is increased.

In addition, it should be noted that, it can be challenging to achieve characteristics required by a semiconductor device (except the on resistance) if doped layers having smaller resistivities are used in the aim of reducing the on resistance. By appropriating utilizing doped layers having larger resistivities, various characteristics required by semiconductor device can be achieved. For example, the second doped layer 36 and the third doped layer 38 (having resistivities greater than that of the first doped layer 34) of this embodiment can be used to obtain the depletion layer spreading and electric field distribution needed in the semiconductor layer 12.

As described above, in experiment example 3 corresponding to the semiconductor device 10 of this embodiment, an increase in the on resistance can be suppressed and the allowable avalanche current can be increased.

The semiconductor device 10 of the embodiment provides the following advantages.

(1) A semiconductor device 10 includes a vertical transistor 42, and a semiconductor layer 12 forming a portion of the vertical transistor 42. The semiconductor layer 12 includes a first doped layer 34, a second doped layer 36 formed on the first doped layer 34, and a third doped layer 38 formed on the second doped layer 36. An n-type impurity concentration of the first doped layer 34 is greater than an n-type impurity concentration of the third doped layer 38, and an n-type impurity concentration of the second doped layer 36 is less than the n-type impurity concentration of the third doped layer 38.

According to the configuration above, an increase in an on resistance of the semiconductor device 10 is suppressed, and an avalanche allowance is increased.

(2) The semiconductor device 10 further includes a gate trench 28 formed in the semiconductor layer 12, and a gate electrode 46 disposed in the gate trench 28. The gate trench 28 passes through the third doped layer 38 and reaches the second doped layer 36.

According to the configuration above, at least a portion of the gate trench 28 is disposed in the second doped layer 36 having a larger resistivity, and thus a withstand voltage of the semiconductor device 10 can be increased.

(3) The gate trench 28 has a bottom wall 28B. At least a portion of the bottom wall 28B is formed in the second doped layer 36.

According to the configuration above, the bottom wall 28B of the gate trench 28 of which an electric field strength easily increases and its peripherals are disposed in the second doped layer 36 having a larger resistivity, and thus a withstand voltage of the semiconductor device 10 can be effectively increased.

(4) The semiconductor device 10 further includes a field plate electrode 48 disposed within the gate trench 28.

According to the configuration above, a gate-drain capacitance can be reduced, and a withstand voltage of the semiconductor device 10 can be increased.

(5) The first doped layer 34 is thinner than the third doped layer 38, and the second doped layer 36 is thicker than the third doped layer 38.

According to the configuration above, the second doped layer 36 having a larger resistivity is formed to be thicker than the first doped layer 34 and the third doped layer 38, and thus the withstand voltage of the semiconductor device 10 can be maintained, and the on resistance can be reduced.

(6) The n-type impurity concentration of the first doped layer 34 is between about 1×10¹⁶ cm⁻³ and 1×10¹⁹ cm⁻³, the n-type impurity concentration of the second doped layer 36 is between about 1×10¹³ cm⁻³ and 1×10¹⁶ cm⁻³, and n-type impurity concentration of the third doped layer 38 is between about 2×10¹⁵ cm⁻³ and 1×10¹⁸ cm⁻³.

According to the configuration above, a depletion layer can fully spread in the semiconductor layer 12, so a required electric field distribution can be obtained in the semiconductor layer 12.

### Other Variation Examples

The embodiment can be modified as follows and be accordingly implemented.
An planar layout of the gate wiring 16 and the source wiring 18 is not limited to the example in FIG. 1. For example, in addition to including the gate extension portions 22, the gate wiring 16 can further include a gate finger (omitted from the drawing) passing through a center of a chip in the plan view. Moreover, for example, the source wiring 18 can exclude the peripheral section 26 (the source finger).
The configuration of the gate trench 28 is not limited to the example shown in FIG. 2. The configuration of the gate trench 28 can be appropriately determined according to characteristics needed by the semiconductor device 10. For example, the gate trench 28 can also have a mesh shape in the plan view.
The cross-section structure of the vertical transistor 42 is not limited to the example shown in FIG. 3. For example, the gate electrode 46 can be buried in the gate trench 28, and the field electrode 48 is not buried in the gate trench 28.
Alternatively, a high-concentration region having an n-type impurity concentration greater than that of the second doped layer can also be formed near a bottom of the peripheral trench 30.
Alternatively, a structure in which conductivity types of individual regions in the semiconductor layer 12 are inverted can also be adopted. That is to say, a p-type region can be an n-type region, and an n-type region can be a p-type region.

One or more examples given in the present detailed description can be combined within scopes that are non-technically contradictory.

In the present detailed description, the expression “at least one of A and B” should be understood as “only A, or only B, or both of A and B”.

The term “on/over” used in the present detailed description includes meanings of “on/over” and “above”, unless otherwise specified according to the context. Thus, the expression “a first layer formed on a second layer” can refer to that the first layer is in contact with the second layer and directly disposed on the second layer in some embodiments, or can refer to that the first layer is not in contact with the second layer and is disposed over or above the second layer. That is to say, the expression “on” does not eliminate a structure having another layer between the first layer and the second layer.

Directional terms such as “vertical”, “horizontal”, “upward”, “downward”, “above”, “below”, “front”, “back”, “vertical”, “lateral”, “left” “right,” or the like are used herein, depending on a particular orientation of the device described and illustrated. Various alternative orientations may be used in the present disclosure. Therefore, these directional terms should not be construed narrowly.

For example, a Z axis direction used herein does not necessarily have to be a vertical direction, nor does it need to completely coincide with the vertical direction. For example, an X axis direction may be a vertical direction, or a Y axis direction may be a vertical direction.

### [Note]

The technical ideas that can be grasped from each of the above embodiments and modified examples are described below. Note that the reference numerals of constituent elements in the embodiment corresponding to the constituent elements described in the supplementary notes are shown in parentheses. The symbols are shown as examples to aid understanding, and the components described in each appendix should not be limited to the components indicated by the symbols.

### [Note 1]

A semiconductor device (10), comprising:
a vertical transistor (42); and
a semiconductor layer (12), forming a portion of the vertical transistor (42), wherein the semiconductor layer (12) includes:
a first doped layer (34);
a second doped layer (36), formed on the first doped layer (34); and
a third doped layer (38), formed on the second doped layer (36), wherein
   an impurity concentration of a first conductivity type of the first doped layer (34) is greater than
   an impurity concentration of the first conductivity type of the third doped layer (38), and
   an impurity concentration of the first conductivity type of the second doped layer (36) is less than
   the impurity concentration of the first conductivity type of the third doped layer (38).

### [Note 2]

The semiconductor device (10) of Note 1, further comprising:
a gate trench (28), formed in the semiconductor layer (12); and
a gate electrode (46), disposed in the gate trench (28), wherein
the gate trench (28) extends through the third doped layer (38) and reaches the second doped layer (36).

### [Note 3]

The semiconductor device (10) of Note 2, wherein the gate trench (28) has a bottom wall (28B), and at least a portion of the bottom wall (28B) is formed in the second doped layer (36).

### [Note 4]

The semiconductor device (10) of Note 2 or 3, further comprising:
an insulating layer (14), formed on the semiconductor layer (12); and
a gate wiring (16) formed on the insulating layer (14), wherein
the gate electrode (46) is electrically connected to the gate wiring (16).

### [Note 5]

The semiconductor device (10) of any one of Notes 2 to 4, further comprising a field plate electrode (48) disposed within the gate trench (28).

### [Note 6]

The semiconductor device (10) of Note 5, further comprising:
an insulating layer (14), formed on the semiconductor layer (12); and
a source wiring (18), formed on the insulating layer (14), wherein
the field plate electrode (48) is electrically connected to the source wiring (18).

### [Note 7]

The semiconductor device (10) of any one of Notes 2 to 6, wherein the gate trench (28) has a depth between about 2 μm and about 10 μm.

### [Note 8]

The semiconductor device (10) of any one of Notes 2 to 7, wherein the gate trench (28) is one of a plurality of gate trenches (28) arranged in stripes in a plan view.

### [Note 9]

The semiconductor device (10) of any one of Notes 2 to 7, wherein the gate trench (28) is formed in a mesh shape in a plan view.

### [Note 10]

The semiconductor device (10) of any one of Notes 1 to 9, wherein the first doped layer (34) is thinner than the third doped layer (38), and the second doped layer (36) is thicker than the third doped layer (38).

### [Note 11]

The semiconductor device (10) of any one of Notes 1 to 10, wherein
a resistivity of the first doped layer (34) is less than a resistivity of the third doped layer (38), and
a resistivity of the second doped layer (36) is greater than the resistivity of the third doped layer (38).

### [Note 12]

The semiconductor device (10) of any one of Notes 1 to 11, wherein
the impurity concentration of the first conductivity type of the first doped layer (34) is between about 1× 10¹⁶ cm⁻³ and about 1×10¹⁹ cm⁻³,
the impurity concentration of the first conductivity type of the second doped layer (36) is between about 1× 10¹³ cm⁻³ and about 1×10¹⁶ cm⁻³, and
the impurity concentration of the first conductivity type of the third doped layer (38) is between about 2× 10¹⁵ cm⁻³ and about 1×10¹⁸ cm⁻³.

### [Note 13]

The semiconductor device (10) of any one of Notes 1 to 12, wherein
a thickness of the first doped layer (34) is between about 0.5 μm and about 10 μm,
a thickness of the second doped layer (36) is between about 1 μm and about 30 μm, and
a thickness of the third doped layer (38) is between about 1 μm and about 15 μm.

### [Note 14]

The semiconductor device (10) of any one of Notes 1 to 13, wherein
a resistivity of the first doped layer (34) is between about 0.01 Ω·cme and about 0.5 Ω·cm,
a resistivity of the second doped layer (36) is between about 0.1 Ω·cm and about 10 Ω·cm,
a resistivity of the third doped layer (38) is between about 0.05 Ω·cm and about 1 Ω·cm.

### [Note 15]

The semiconductor device (10) of any one of Notes 1 to 14, wherein an ion implantation region (40) of a second conductivity type is formed in the third doped layer (38).

### [Note 16]

The semiconductor device (10) of any one of Notes 1 to 15, wherein a body region (52) of a second conductivity type and a source region (50) of the first conductivity type of the vertical transistor (42) are formed in the third doped layer (38).

### [Note 17]

The semiconductor device (10) of any one of Notes 1 to 16, wherein the semiconductor layer (12) further includes a semiconductor substrate (32), and the first doped layer (34) is formed on the semiconductor substrate (32).

### [Note 18]

The semiconductor device (10) of any one of Notes 2 to 17, wherein
the semiconductor layer (12) has a first surface (12A) and a second surface (12B) opposite to the first surface (12A),
the gate trench (28) is formed on the first surface (12A) of the semiconductor layer (12), and
the semiconductor device (10) further includes a drain electrode (44) formed on the second surface (12B) of the semiconductor layer (12).

### [Note 19]

The semiconductor device (10) of any one of Notes 1 to 18, wherein the vertical transistor (42) is a trench-gate-type MOSFET.

### [Note 20]

The semiconductor device (10) of any one of Notes 1 to 19, wherein when the vertical transistor (42) is turned on, a current flows through the first doped layer (34), the second doped layer (36) and the third doped layer (38).

The above description is merely illustrative. Those skilled in the art will recognize that many more possible combinations and permutations are possible beyond those listed for the purpose of describing the techniques of the present disclosure. The present disclosure is intended to cover all alternatives, variations, and modifications falling within the scope of this disclosure, including the claims.

1. A semiconductor device, comprising:
a vertical transistor; and
a semiconductor layer, forming a portion of the vertical transistor, wherein the semiconductor layer includes:
a first doped layer;
a second doped layer, formed on the first doped layer; and
a third doped layer, formed on the second doped layer, wherein
an impurity concentration of a first conductivity type of the first doped layer is greater than
an impurity concentration of the first conductivity type of the third doped layer, and
an impurity concentration of the first conductivity type of the second doped layer is less than
the impurity concentration of the first conductivity type of the third doped layer.

2. The semiconductor device of claim 1, further comprising:
a gate trench, formed in the semiconductor layer; and
a gate electrode, disposed in the gate trench, wherein
the gate trench extends through the third doped layer and reaches the second doped layer.

3. The semiconductor device of claim 2, wherein the gate trench has a bottom wall, and at least a portion of the bottom wall is formed in the second doped layer.

4. The semiconductor device of claim 2, further comprising:
an insulating layer, formed on the semiconductor layer; and
a gate wiring formed on the insulating layer, wherein
the gate electrode is electrically connected to the gate wiring.

5. The semiconductor device of claim 2, further comprising a field plate electrode disposed within the gate trench.

6. The semiconductor device of claim 5, further comprising:
an insulating layer, formed on the semiconductor layer; and
a source wiring, formed on the insulating layer, wherein
the field plate electrode is electrically connected to the source wiring.

7. The semiconductor device of claim 2, wherein the gate trench has a depth between about 2 μm and about 10 μm.

8. The semiconductor device of claim 2, wherein the gate trench is one of a plurality of gate trenches arranged in stripes in a plan view.

9. The semiconductor device of claim 2, wherein the gate trench is formed in a mesh shape in a plan view.

10. The semiconductor device of claim 1, wherein
the first doped layer is thinner than the third doped layer, and
the second doped layer is thicker than the third doped layer.

11. The semiconductor device of claim 1, wherein
a resistivity of the first doped layer is less than a resistivity of the third doped layer, and
a resistivity of the second doped layer is greater than the resistivity of the third doped layer.

12. The semiconductor device of claim 1, wherein
the impurity concentration of the first conductivity type of the first doped layer is between about 1×10¹⁶ cm⁻³ and about 1×10¹⁹ cm⁻³,
the impurity concentration of the first conductivity type of the second doped layer is between about 1×10¹³ cm⁻³ and about 1×10¹⁶ cm⁻³, and
the impurity concentration of the first conductivity type of the third doped layer is between about 2×10¹⁵ cm⁻³ and about 1×10¹⁸ cm⁻³.

13. The semiconductor device of claim 1, wherein
a thickness of the first doped layer is between about 0.5 μm and about 10 μm,
a thickness of the second doped layer is between about 1 μm and about 30 μm, and
a thickness of the third doped layer is between about 1 μm and about 15 μm.

14. The semiconductor device of claim 1, wherein
a resistivity of the first doped layer is between about 0.01 Ω·cme and about 0.5 Ω·cm,
a resistivity of the second doped layer is between about 0.1 Ω·cm and about 10 Ω·cm,
a resistivity of the third doped layer is between about 0.05 Ω·cm and about 1 Ω·cm.

15. The semiconductor device of claim 1, wherein an ion implantation region of a second conductivity type is formed in the third doped layer.

16. The semiconductor device of claim 1, wherein a body region of a second conductivity type and a source region of the first conductivity type of the vertical transistor are formed in the third doped layer.

17. The semiconductor device of claim 1, wherein the semiconductor layer further includes a semiconductor substrate, and the first doped layer is formed on the semiconductor substrate.

18. The semiconductor device of claim 2, wherein
the semiconductor layer has a first surface and a second surface opposite to the first surface,
the gate trench is formed on the first surface of the semiconductor layer, and
the semiconductor device further includes a drain electrode formed on the second surface of the semiconductor layer.

19. The semiconductor device of claim 1, wherein the vertical transistor is a trench-gate-type MOSFET.

20. The semiconductor device of claim 1, wherein when the vertical transistor is turned on, a current flows through the first doped layer, the second doped layer and the third doped layer.
